(19) United States
(12) Patent Application Publication
(10) Pub. No.: US 2020/0057491 A1
(43) Pub. Date: Feb. 20, 2020

(54) DISPLAY SYSTEM, DRIVER INTEGRATED CIRCUIT APPLIED TO THE DISPLAY SYSTEM, AND ASSOCIATED METHOD

(71) Applicant: INT TECH CO., LTD., Hsinchu County (TW)

(72) Inventor: CHING-HUA YANG, HSINCHU COUNTY (TW)

(21) Appl. No.: 16/235,240

(22) Filed: Dec. 28, 2018

Related U.S. Application Data
(60) Provisional application No. 62/719,039, filed on Aug. 16, 2018.

(51) Int. Cl. G06F 3/01; G09G 3/20; H04N 5/225

(52) U.S. Cl. CPC G06F 3/013; G09G 3/2074; G09G 2340/0407; G09G 2354/00; H04N 5/225

(57) ABSTRACT

A display system includes an image sensor, a display panel, and a driver integrated circuit (IC). The image sensor is arranged to capture a gaze direction of an observer. The display panel includes a plurality of pixels arranged in a pixel array, and a first conductive lines coupled to a first transistor in a gaze zone in the pixel array. The first conductive line is arranged to carry signal to the first transistor. The driver IC is coupled to the image sensor and the display panel, and includes a selecting circuit. The selecting circuit is arranged to selectively transmit a first signal to the first transistor in the gaze zone via the first conductive line according to the gaze direction.

### BACKGROUND

The present disclosure relates to a display system, and more particularly, to a display system applying eye tracking technique, a driver integrated circuit applied to the display panel and an associated method.

With the growing need of larger display panel, the amount of gate lines and source lines installed within the panel are correspondingly increased. Accordingly, the gate driver integrated circuit (IC) and the source driver IC are required to manage more signals, which results in a high density of metal lines served as gate lines and source lines connecting between the driver ICs and the display panel. With such configurations, the electromagnetic interference (EMI) may severely interfere the performance of the driver ICs and the quality of display.

### SUMMARY OF THE INVENTION

Therefore, one of the objectives of the present disclosure is to provide a display system and an associated driver integrated circuit applied to the display system to solve the aforementioned problems.

According to an embodiment of the present disclosure, a display system is disclosed. The display system includes an image sensor, a display panel, and a driver integrated circuit (IC). The image sensor is arranged to capture a gaze direction of an observer. The display panel includes a plurality of pixels arranged in a pixel array, and a first conductive lines coupled to a first transistor in a gaze zone in the pixel array. The first conductive line is arranged to carry signal to the first transistor. The driver IC is coupled to the image sensor and the display panel, and includes a selecting circuit. The selecting circuit is arranged to selectively transmit a first signal to the first transistor in the gaze zone via the first conductive line according to the gaze direction.

According to an embodiment of the present disclosure, a driver IC applied to a display system. The display system includes an image sensor and a display panel, where the image sensor is arranged to capture a gaze direction of an observer to generate a gaze information. The display panel includes a plurality of pixel arranged in a pixel array and a first conductive line coupled to a first transistor in a gaze zone in the pixel array. The driver IC includes a signal generating circuit and a selecting circuit. The signal generating circuit is arranged to generate a first signal and transmit the first signal toward the first conductive line. The selecting circuit is arranged to selectively transmit the first signal from the signal generating circuit to the first transistor in the gaze zone via the first conductive line according to the gaze direction.

According to an embodiment of the present disclosure, a display system is disclosed. The display system includes an image sensor, a display panel, and a driver IC. The image sensor is arranged to capture a gaze direction of an observer. The display panel includes a plurality of pixels arranged in a pixel array and a plurality of conductive lines, wherein a part of each conductive line straightly extends from one side of the pixel array to an opposite side of the pixel array and couples to each transistor located thereon. The driver IC includes a signal generating circuit and a selecting circuit. The signal generating circuit is arranged to generate a first signal and a second signal. The selecting circuit is arranged to selectively transmit the first signal to a first conductive line and the second signal to a second conductive line adjacent to the first conductive line according to the gaze direction.

According to an embodiment of the present disclosure, a driving method of a display system is disclosed, comprising: arranging a plurality of pixels in a display panel of the display system in a pixel array, wherein the pixel array includes a first number of rows, and each row includes a conductive line; coupling a second number of transfer lines to the conductive lines in the first number of rows, wherein the first number is greater than the second number; and selectively transmitting signals carried on the second number of transfer lines to the transistors located in the first number of rows according to a gaze direction of an observer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating a display panel according to an embodiment of the present disclosure.

FIG. 2 is a diagram illustrating a display system according to an embodiment of the present disclosure.

FIG. 3 is a diagram illustrating a selecting circuit according to an embodiment of the present disclosure.

FIG. 4 is a diagram illustrating the operation of the selecting circuit shown in FIG. 3 according to an embodiment of the present disclosure.

FIG. 5 is a diagram illustrating a display system according to another embodiment of the present disclosure.

FIG. 6 is a diagram illustrating a selecting circuit according to another embodiment of the present disclosure.

FIG. 7 is a diagram illustrating the operation of the selecting circuit shown in FIG. 6 according to an embodiment of the present disclosure.

FIG. 8 is a diagram illustrating a display system according to another embodiment of the present disclosure.

FIG. 9 is a diagram illustrating a display system according to yet another embodiment of the present disclosure.

FIG. 10 is a flowchart illustrating a driving method of a display system according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

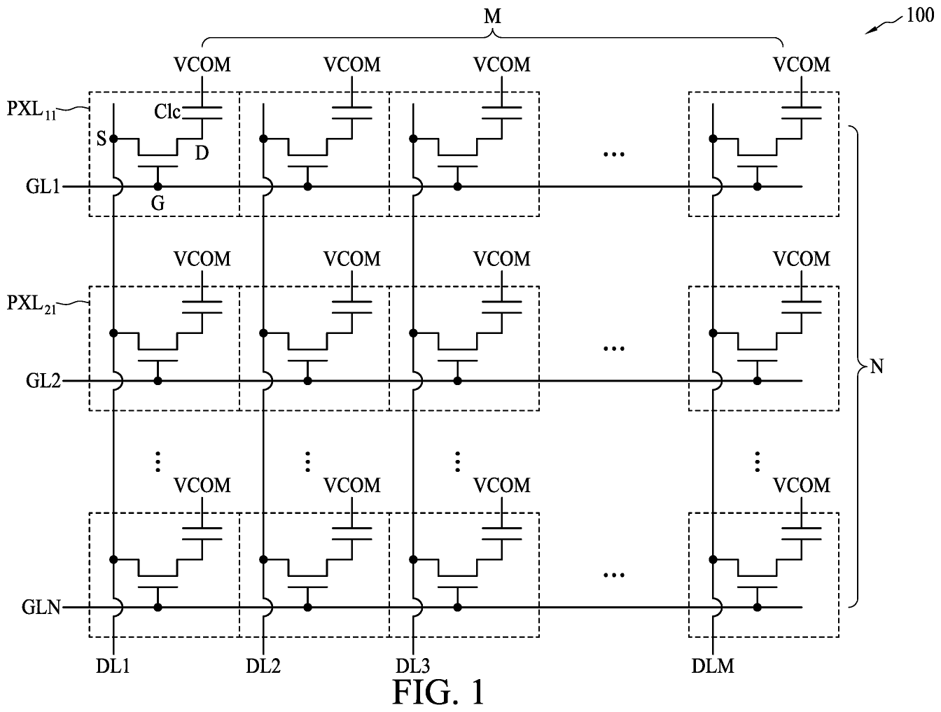

FIG. 1 is a diagram illustrating a display panel 100 according to an embodiment of the present disclosure. The display panel 100 includes a plurality of pixels, e.g., the pixels PXL₁₁, PXL₂₁, and so on, arranged in a pixel array. In this embodiment, the pixel array includes N rows and M columns, where N and M are both nature number. Each pixel (e.g., the pixel PXL₁₁) includes a thin film transistor (TFT) including a gate terminal G, a source terminal S and a drain terminal D. The plurality of transistors are formed on a TFT backplane (now shown). The gate terminals of the transistors located in the same row are connected via a conductive line which is referred to as a gate line or a scan line. For example, the gate terminals of the transistors located in the first row are connected via the gate line GL1. Therefore, the display panel 100 includes N conductive lines arranged to connect gate terminals of those transistors locate in the same row, and further arranged to carry signals to the gate terminals thereof.

On the other hand, the source terminals of the transistors located in the same column are connected via a conductive line which is referred to as a data line. For example, the source terminals of the transistors located in the first column are connected via the data line DL1. Therefore, the display panel 100 includes M conductive lines arranged to connect source terminals of those transistors locate in the same column, and further arranged to carry signals to the source terminals thereof. In addition, a capacitor C1c formed between the drain terminal of each transistor and a common voltage layer VCOM, wherein the common voltage layer is disposed above the TFT backplane. However, the structure of each pixel depicted in FIG. 1 is only for illustrative purpose. In other embodiments, each pixel may include more than one transistor therein. For example, each pixel includes two transistors (T) and one equivalent capacitor (C) which can be referred to as a 2T1C structure. Those skilled in the art should readily understand the structure of the pixel circuit, the detailed description is omitted here for brevity.

It should be noted that each pixel (e.g., the pixel PXL₁₁) may include more than one sub-pixel. For example, each pixel includes three sub-pixels (i.e., red, green, blue), that is, each pixel includes at least three transistors. However, this is only for illustrative purpose, it should not be limited by the present disclosure.

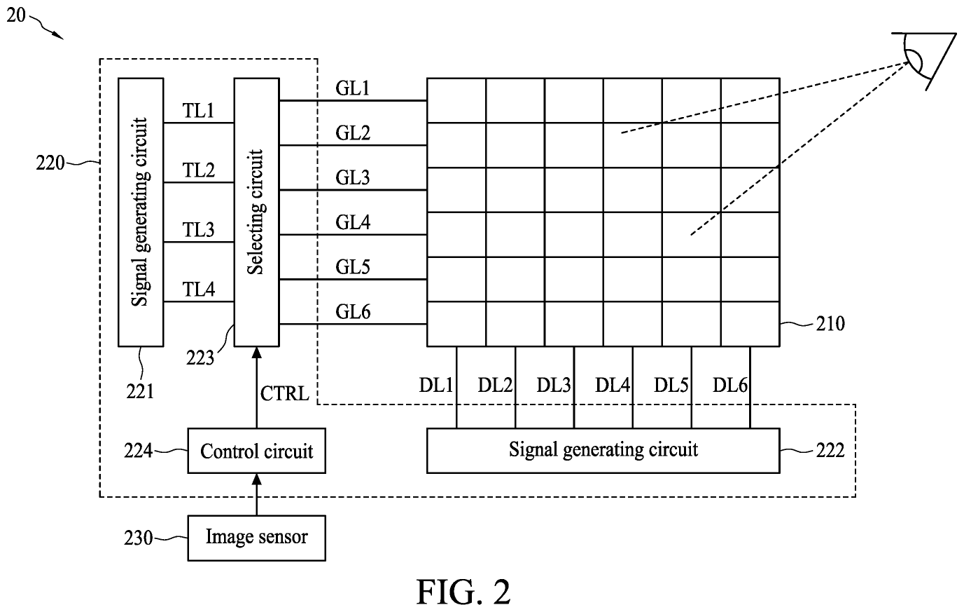

FIG. 2 is a diagram illustrating a display system 20 according to an embodiment of the present disclosure. As shown in FIG. 2, the display system 20 includes a display panel 210, a driver integrated circuit (IC) 220, and an image sensor 230, wherein the display panel 210 can be implemented by the display panel 100. It should be noted that the number of pixels included in the display panel 210 is only for illustrative purpose, it should not be limited by the present disclosure. In this embodiment, the natural number N and M are illustrated as 6, that is, the display panel 210 includes a 6*6 pixel array. As mentioned in the embodiment of FIG. 1, the display panel 210 includes 6 conductive lines, i.e. the scan lines GL1-GL6, and each connects to the gate terminals of those transistors locate in the same row. In addition, the display panel further includes 6 conductive lines, i.e. the data lines DL1-DL6, and each connects to the source terminals of those transistors locate in the same column.

The driver IC 220 includes signal generating circuits 221 and 222, a selecting circuit 223, and a control circuit 224. The selecting circuit 223 couples to the display panel 210 via the scan lines GL1-GL6, and transfers signals from the signal generating circuit 221 to the gate terminals of the transistors in the display panel 210 via the scan lines GL1-GL6. With such configurations, the signal generating circuit 221 is referred to as a gate driver arranged to provide signals to the gate terminal of the transistors in the display panel 210. In one embodiment, when the display panel 210 operates in a display phase, the signal generating circuit 221 sequentially generates an impulse signal toward each scan line. In another embodiment, when the display panel operates in a touch phase, the signal generating circuit 221 provides a signal whose direct current (DC) voltage level is below 0 volt to turn off the transistors in the display panel 210. However, this is only for illustrative purpose, the profile of the signals generated by the signal generating circuit 221 should not be limited by the present disclosure. The signals generated by the signal generating circuit 221 are transmitted to the selecting circuit 223 via transfer lines TL1-TL4.

In this present disclosure, the number of transfer lines is smaller than the number of the conductive lines, and the transfer lines are utilized to transmitting signals from the signal generating circuit 221 to the display panel. With such configuration, the density of metal lines connecting from the signal generating circuit 221 to the display panel can be reduced to mitigate the electromagnetic interference (EMI).

The signal generating circuit 222 couples to the display panel 210 via the data lines DL1-DL6, and is arrange to provide signals to the source terminals of transistors in the display panel 210 via the data lines DL1-DL6. With such configurations, the signal generating circuit 222 is referred to as the source driver. In one embodiment, when the display panel 210 operates in a display phase, the signal generating circuit 221 generates image data toward each data line.

The image sensor 230 is arranged to capture a gaze direction of an observer using the display device 20. In one embodiment, the image sensor 230 may be implemented by a camera. The camera captures the image reflected on the eyes of the observer to determine which zone of the display zone 210 is gaze by the observer. However, the operation of the image sensor 230 is not limited by the present disclosure. The information of the gaze direction is transmitted to the control circuit 224 to generate a control signal CTRL according to the gaze direction.

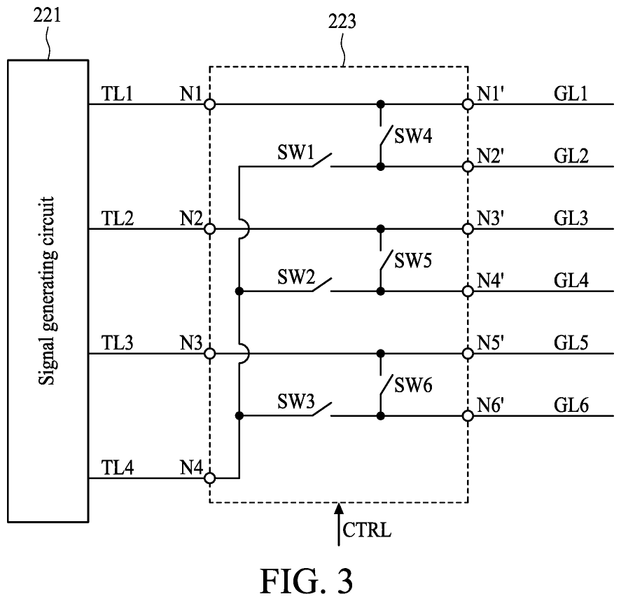

FIG. 3 is a diagram illustrating a selecting circuit 300 according to an embodiment of the present disclosure. As shown in FIG. 3, the selecting circuit 223 includes nodes N1 to N4 to couple to the signal generating circuit 221 via the transfer lines TL1 to TL4, respectively. In addition, the selecting circuit 223 includes nodes N1′ to N6′ to couple to the display panel 230 via the scan lines GL1 to GL6, respectively. The selecting circuit 223 further includes switches SW1 to SW6. More specifically, the transfer line TL1 connects to the scan line GL1 via the selecting circuit 223, the transfer line TL2 connects to the scan line GL3 via the selecting circuit 223, the transfer line TL3 connects to the scan line GL5 via the selecting circuit 223, and the transfer line TL4 couples to the scan lines GL2, GL4 and GL6 via the switches SW1 to SW3, respectively. The transfer line TL1 couples to the scan line GL2 via the switch SW4, the transfer line TL2 couples to the scan line GL4 via the switch SW5, and the transfer line TL3 couples to the scan line GL6 via the switch SW6. The switch statuses of the switches SW1 to SW6 is controlled by the control signal CTRL from the control circuit 224 according to the gaze direction.

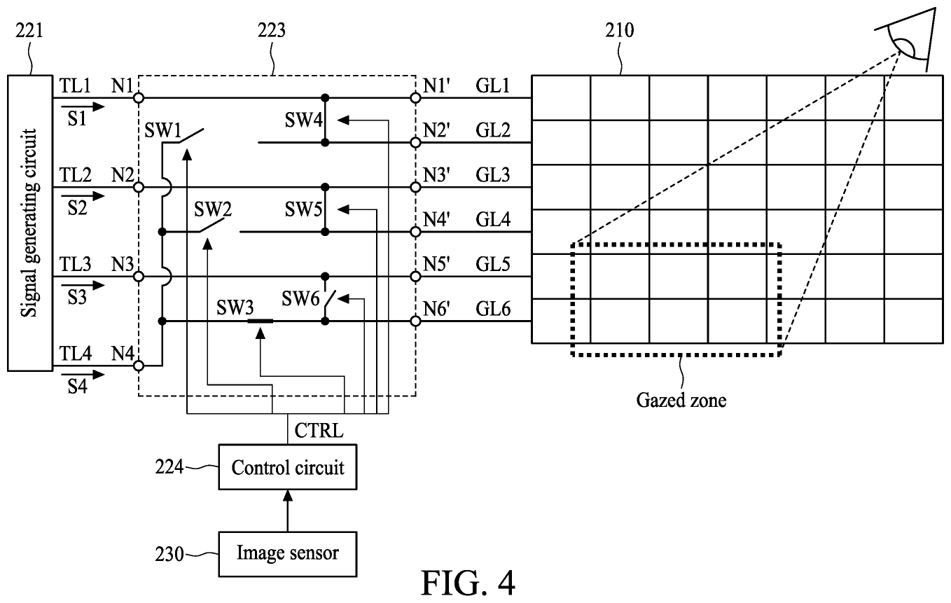

FIG. 4 is a diagram illustrating the operation of the selecting circuit 223 shown in FIG. 3 according to an embodiment of the present disclosure. When the image sensor 230 captures the gaze direction of the observer, the control circuit 224 transmits the control signal CTRL according to the gaze direction to the selecting circuit 223. In this embodiment, the gaze direction is toward a gaze zone (e.g., the dash line marked zone) covering the scan lines GL5 and GL6. According to the control signal CTRL, the switches SW3, SW4 and SW5 are activated while the switches SW1, SW2 and SW6 are deactivated. With such configurations, a signal S1 on the transfer line TL1 is transmitted to the scan lines GL1 and the GL2 via the selecting circuit 223, a signal S2 on the transfer line TL2 is transmitted to the scan lines GL3 and the GL4 via the selecting circuit 223, and a signal S3 on the transfer line TL3 is transmitted to the scan line GL4 via the selecting circuit 223. In addition, a signal S4 on the transfer line TL4 is transmitted to the scan line GL6 via the selecting circuit 223.

By the operation of the selecting circuit 223, the signals on the scan lines GL5 and GL6 are respectively generated from the signal generating circuit 221, that is, the image data displayed on the gaze zone remains accurate. On the other hand, the signal carried on the scan line GL2 is same as the signal carried on the scan line GL1, and the signal carried on the scan line GL4 is same as the signal carried on the scan line GL3. The image data displayed on the zone excluding the gaze zone (e.g., from the scan lines GL1 to GL4) may not be accurate as that on the gaze zone. However, this minor distortion may not be observed since the observer using the display system 20 is observing the gaze zone. By transmitting the signal on one scan line (e.g., the scan lines GL1) to an adjacent scan line (e.g., the scan lines GL2) instead of generating a signal for each scan line, the burden of the signal generating circuit 221 is accordingly reduced.

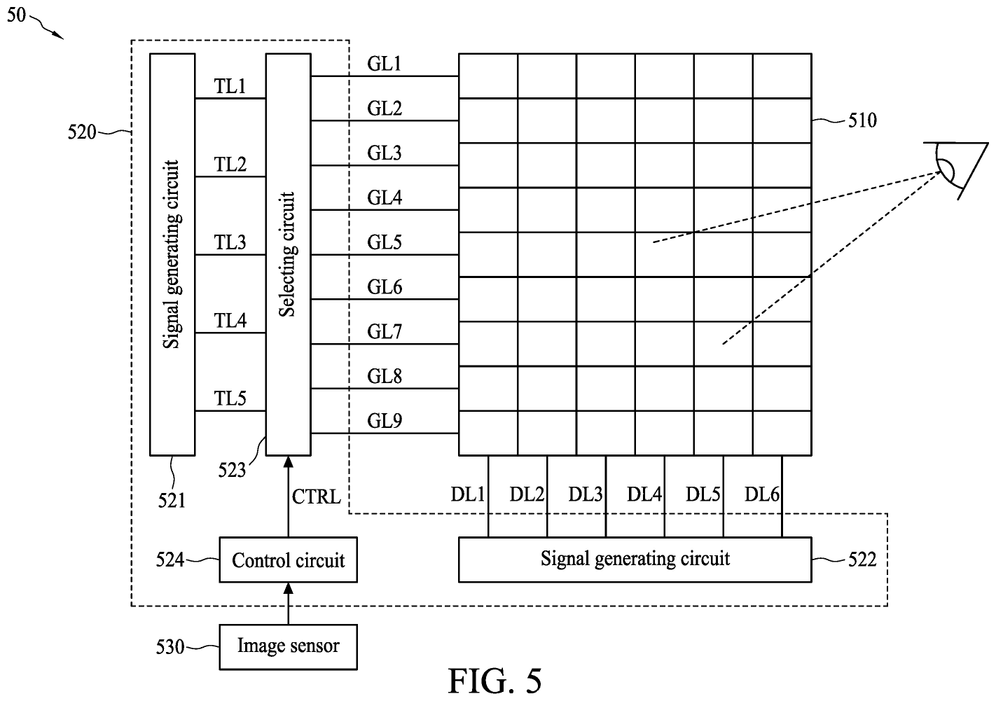

With the growing need of larger display panel, the burden of the gate driver can be greatly reduced by adapting the display system proposed by the present disclosure. FIG. 5 is a diagram illustrating a display system 50 according to another embodiment of the present disclosure. As shown in FIG. 5, the display system 50 includes a display panel 510, a driver integrated circuit (IC) 520, and an image sensor 530, wherein the display panel 510 can be implemented by the display panel 100. It should be noted that the number of pixels included in the display panel 510 is only for illustrative purpose, it should not be limited by the present disclosure. In this embodiment, the natural number N and M are illustrated as 9 and 6, respectively, that is, the display panel 510 includes a 9*6 pixel array. As mentioned in the embodiment of FIG. 1, the display panel 510 includes 9 conductive lines, i.e. the scan lines GL1-GL9, and each connects the gate terminals of those transistors locate in the same row. In addition, the display panel 510 further includes 6 conductive lines, i.e. the data lines DL1-DL6, and each connects the source terminals of those transistor locate in the same column.

The driver IC 520 is similar to the driver IC 220 described in FIG. 2. The driver IC 520 includes signal generating circuits 521 and 522, a selecting circuit 523, and a control circuit 524. The selecting circuit 523 couples to the display panel 510 via the scan lines GL1-GL9, and transmits signals from the signal generating circuit 521 to the gate terminals of the transistors in the display panel 510 via the scan lines GL1-GL9. With such configurations, the signal generating circuit 521 is referred to as a gate driver arranged to provide signals to the gate terminal of the transistors in the display panel 510. In one embodiment, when the display panel 510 operates in a display phase, the signal generating circuit 521 sequentially generates an impulse signal toward each scan line. In another embodiment, when the display panel operates in a touch phase, the signal generating circuit 521 provides a signal whose DC voltage level is below 0 volt to turn off the transistors in the display panel 510. However, this is only for illustrative purpose, the profile of the signals generated by the signal generating circuit 521 should not be limited by the present disclosure. The signals generated by the signal generating circuit 521 are transmitted to the selecting circuit 523 via transfer lines TL1-TL5, wherein the transfer lines (e.g., 5) are fewer than the scan lines (e.g., 9).

The signal generating circuit 522, the control circuit 524 and the image sensor 530 are similar to those described in FIG. 2. The detailed description is omitted for brevity.

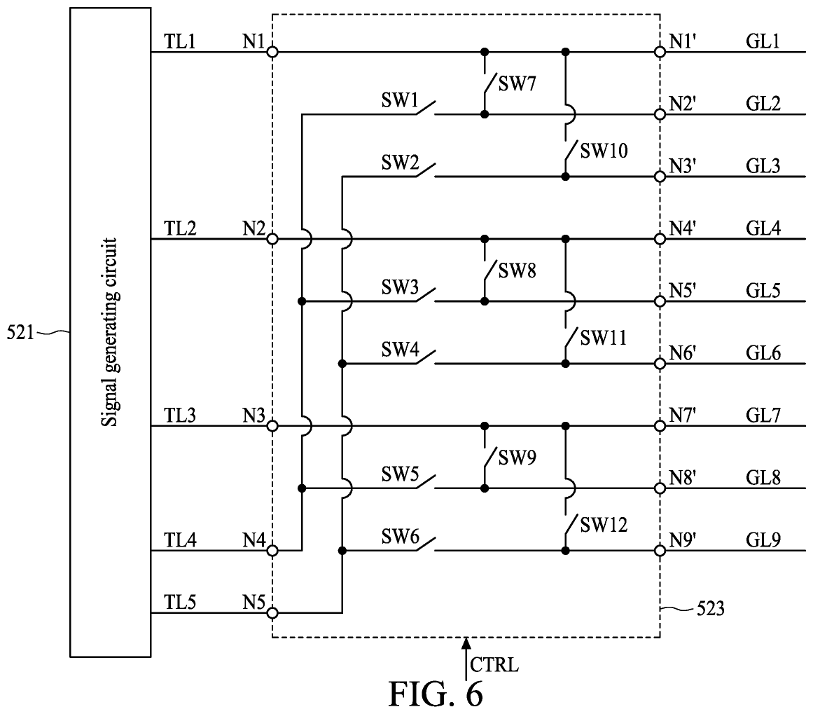

FIG. 6 is a diagram illustrating the selecting circuit 523 according to another embodiment of the present disclosure. The selecting circuit 523 is coupled to the display panel 510 having more pixels and scan lines. As shown in FIG. 5, the selecting circuit 523 includes nodes N1 to N5 to couple to the signal generating circuit 521 via the transfer lines TL1 to TL5, respectively. In addition, the selecting circuit 523 includes nodes N1′ to N9′ to couple to the larger display panel via the scan lines GL1 to GL9, respectively. The selecting circuit 523 further includes switches SW1 to SW12.

More specifically, the transfer line TL1 connects to the scan line GL1 via the selecting circuit 523, the transfer line TL2 connects to the scan line GL4 via the selecting circuit 523, and the transfer line TL3 connects to the scan line GL7 via the selecting circuit 523. The transfer line TL4 couples to the scan lines GL2, GL5 and GL8 via the switches SW1, SW3, and SW5, respectively, and the transfer line TL5 couples to the scan lines GL3, GL6 and GL9 via the switches SW2, SW4, and SW6, respectively. The transfer line TL1 couples to the scan lines GL2 via the switch SW7 and couples to the scan lines GL3 via the switch SW10. The transfer line TL2 couples to the scan line GL5 via the switch SW8 and couples to the scan line GL6 via the switch SW11. The transfer line TL3 couples to the scan line GL8 via the switch SW9 and couples to the scan line GL9 via the switch SW12. The switch statuses of the switches SW1 to SW12 is controlled by the control signal CTRL from the control circuit 524 according to the gaze direction.

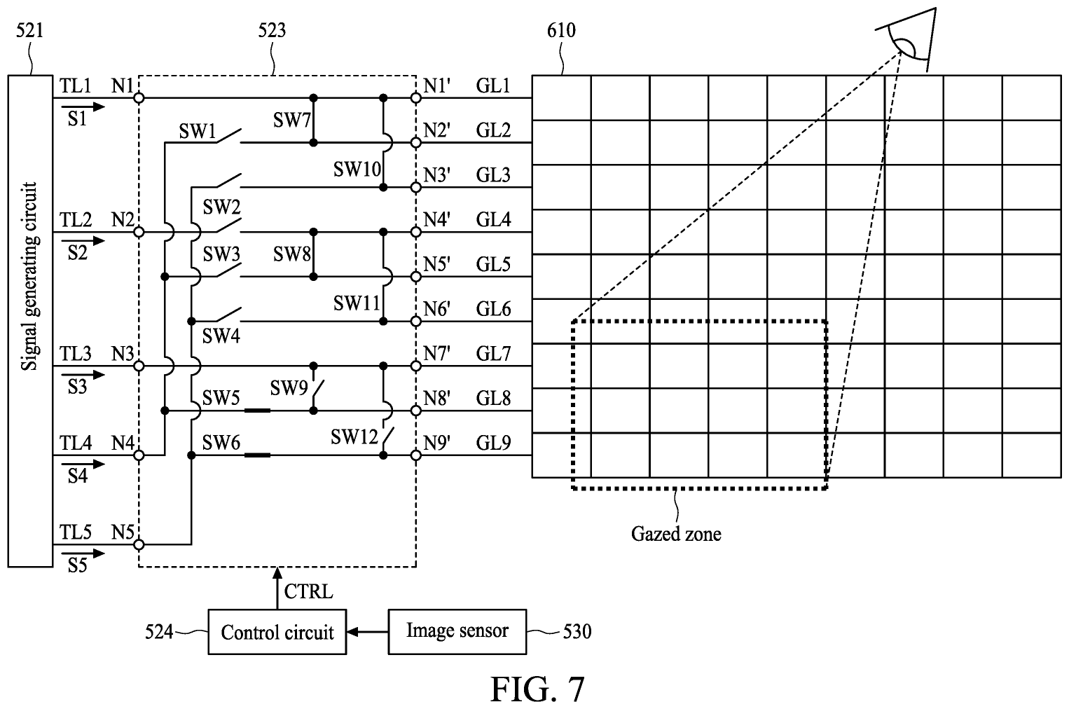

FIG. 7 is a diagram illustrating the operation of the selecting circuit 523 shown in FIG. 6 according to an embodiment of the present disclosure. When the image sensor 530 captures the gaze direction of the observer, the control circuit 524 transmits the control signal CTRL according to the gaze direction to the selecting circuit 523. In this embodiment, the gaze direction towards a gaze zone (e.g., the dash line marked zone) covering the scan lines GL7 to GL9 of the display panel 510. According to the control signal CTRL the switches SW5, SW6, SW7, SW8, SW10 and SW11 are activated while the switches SW1, SW2, SW3, SW4, SW9 and SW12 are deactivated. For the simplicity, the connections between the switches SW1 to SW12 and the control signal CTRL are omitted here. With such configurations, a signal S1 on the transfer line TL1 is transmitted to the scan lines GL1, GL2 and GL3 via the selecting circuit 523, a signal S2 on the transfer line TL2 is transmitted to the scan lines GL4, GL5 and GL6 via the selecting circuit 523, and a signal S3 on the transfer line TL3 is transmitted to the scan line GL7 via the selecting circuit 523. In addition, a signal S4 on the transfer line TL4 is transmitted to the scan line GL8 via the selecting circuit 523, and a signal S5 on the transfer line TL5 is transmitted to the scan line GL9 via the selecting circuit 523.

By the operation of the selecting circuit 523, the signals on the scan lines GL7, GL8 and GL9 are respectively generated from the signal generating circuit 521, that is, the image data displayed on the gaze zone remains accurate. On the other hand, the signals carried on the scan lines GL2 and GL3 are same as the signal carried on the scan line GL1, and the signals carried on the scan lines GL5 and GL6 are same as the signal carried on the scan line GL4. The image data displayed on the zone excluding the gaze zone (e.g., from the scan lines GL1 to GL6) may not be accurate as that on the gaze zone. However, this minor distortion may not be observed since the person using the display system 50 is observing the gaze zone. By transferring the signal on one scan line (e.g., the scan lines GL1) to adjacent scan lines (e.g., the scan lines GL2 and GL3) instead of generating a signal for each scan line, the burden of the signal generating circuit 521 is accordingly reduced.

According to the embodiments of FIG. 2 to FIG. 7, the burden of the signal generating circuit can be greatly reduced by adapting the display system proposed by the present disclosure when the resolution of the display panel is getting bigger, e.g., more than one thousand scan lines are included in the panel.

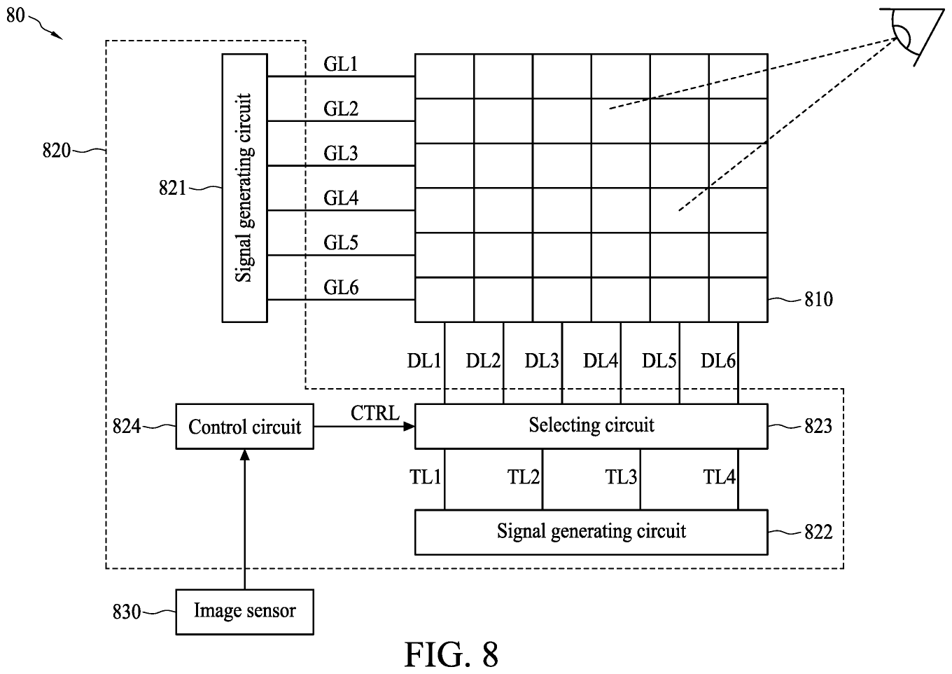

It should be noted that the selecting circuits 223 and 523 are not limited to be adapted on the scan lines. In other embodiments, the selecting circuit can be applied to data lines connecting the source terminals of the transistors in the display panel. FIG. 8 is a diagram illustrating a display system 80 according to another embodiment of the present disclosure. The display system 80 is similar to the display system 20 described in FIG. 2 except the selecting circuit 823 couples to the display panel 810 via the data lines DL1-DL6, and transmits signals from the signal generating circuit 822 to the source terminals of the transistors in the display panel 810 via the data lines DL1-DL6. Those skilled in the art should readily understand the operation of the display system 80 after reading the embodiments of FIG. 2 and FIG. 5, the detailed description is omitted here for brevity.

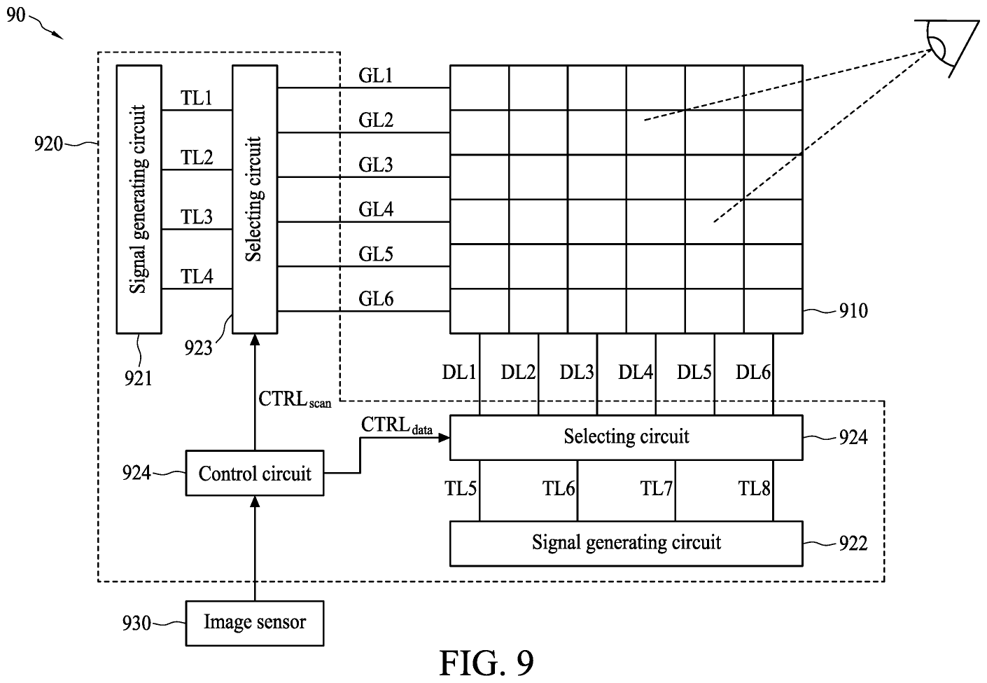

In addition, the selecting circuit proposed by the present disclosure can be applied to the scan lines and the data lines at the same time. FIG. 9 is a diagram illustrating a display system 90 according to yet another embodiment of the present disclosure. The display system 90 is similar to the display systems 20, 50, 80 described in FIGS. 2, 5 and 8, respectively, except the display system 90 includes selecting circuits 923 and 924. The selecting circuit 923 couples to the display panel 910 via the scan lines GL1-GL6, and transmits signals from the signal generating circuit 921 to the gate terminals of the transistors in the display panel 910 via the scan lines GL1-GL6. The selecting circuit 924 couples to the display panel 910 via the data lines DL1-DL6, and transmits signals from the signal generating circuit 922 to the source terminals of the transistors in the display panel 910 via the data lines DL1-DL6. The control circuit 924 generates a control signal CTRL_{scan} according to the gaze direction, and transmits the control signal CTRL_{scan} to the selecting circuit 923. The control circuit 924 further generates a control signal CTRL_{data} according to the gaze direction, and transmits the control signal CTRL_{data} to the selecting circuit 924. Those skilled in the art should readily understand the operation of the display system 90 after reading the embodiments of FIGS. 2, 5, and 8, the detailed description is omitted here for brevity.

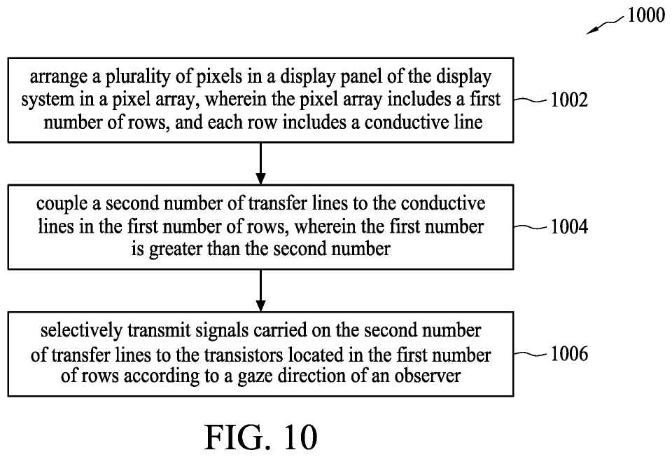

FIG. 10 is a flowchart illustrating a driving method 1000 of a display system according to an embodiment of the present disclosure. Provided that the results are substantially the same, the steps shown in FIG. 10 are not required to be executed in the exact order described, and other orders may be followed. The method 1000 is summarized as follows.
Step 1002: a plurality of pixels in a display panel of the display system are arranged in a pixel array, wherein the pixel array includes a first number of rows, and each row includes a conductive line.
Step 1004: a second number of transfer lines are coupled to the conductive lines in the first number of rows, wherein the first number is greater than the second number.
Step 1006: signals carried on the second number of transfer lines are selectively transmitted to the transistors located in the first number of rows according to a gaze direction of an observer. Those skilled in the art should readily understand the driving method 1000 after reading the paragraphs above. The detailed description is omitted herein for brevity.

What is claimed is:

1. A display system, comprising:
an image sensor, arranged to capture a gaze direction of an observer;
a display panel, including:
a plurality of pixels arranged in a pixel array; and
a first conductive line, coupled to a first transistor in a gaze zone in the pixel array, wherein the first conductive line is arranged to carry signal to the first transistor; and
a driver integrated circuit (IC), coupled to the image sensor and the display panel, including:
a selecting circuit, arranged to selectively transmit a first signal to the first transistor in the gaze zone via the first conductive line according to the gaze direction.

2. The display system of claim 1, wherein the selecting circuit transmits the first signal to the first transistor in the gaze zone via the first conductive line when the gaze direction is toward the gaze zone.

3. The display system of claim 2, wherein the first conductive line is a data line, and the selecting circuit transmits the first signal to a source terminal of the first transistor via the first conductive line in the gaze zone when the gaze direction is toward the gaze zone.

4. The display system of claim 3, wherein the display panel further comprises:
a second conductive line, coupled to a second transistor in the gazezone, wherein the selecting circuit transmits a second signal to a source terminal of the second transistor via the second conductive line;
wherein the selecting circuit transmits the second signal to the source terminal of the first transistor via the first conductive line when the gaze direction is toward a part of the display panel, and the part of the display panel excludes (avoid negtive claiming) the gaze zone.

5. The display system of claim 2, wherein the first conductive line is a scan line, and the selecting circuit transmits the first signal to a gate terminal of the first transistor in the gaze zone via the first conductive line when the gaze direction is toward the gaze zone.

6. The display system of claim 5, further comprising:
a second conductive line, coupled to a second transistor in the gaze zone, wherein the selecting circuit transmits a second signal to a gate terminal of the second transistor via the second conductive line;
wherein the selecting circuit transmits the second signal to the gate terminal of the first transistor via the first conductive line when the gaze direction is toward a part of the display panel, and the part of the display panel excludes the gaze zone.

7. The display system of claim 2, wherein the driver IC further comprises:
a control circuit, arranged to generate a control signal according to the gaze direction;
wherein the selecting circuit includes a switch controlled by the control signal, and the selecting circuit transmits the first signal to the first transistor via the backup line when the control signal activates the switch.

8. A driving circuit applied to a display system, wherein the display system includes an image sensor and a display panel, where the image sensor is arranged to capture a gaze direction of an observer to generate a gaze information, and the display panel includes a plurality of pixel arranged in a pixel array and a first conductive line coupled to a first transistor in a gaze zone in the pixel array, comprising:
a signal generating circuit, arranged to generate a first signal and transmit the first signal toward the first conductive line; and
a selecting circuit, arranged to selectively transmit the first signal from the signal generating circuit to the first transistor in the gaze zone via the first conductive line according to the gaze direction.

9. The driver IC of claim 8, wherein the selecting circuit transmits the first signal to the first transistor in the gaze zone via the first conductive line when the gaze direction is toward the gaze zone.

10. The driver IC of claim 10, wherein the selecting circuit transmits the first signal to a source terminal of the first transistor in the gaze zone via the first conductive line when the gaze direction is toward the gaze zone.

11. The driver IC of claim 10, wherein the signal generating circuit is further arranged to generate a second signal toward a second conductive line of the display panel, and the selecting circuit is further arranged to transmit the second signal to a source terminal of a second transistor in the pixel array via the second conductive line, and the selecting circuit further transmits the second signal to the source terminal of the first transistor via the first conductive line when the gaze direction is toward a part of the display panel, and the part of the display panel excludes the gaze zone.

12. The driver IC of claim 9, wherein the selecting circuit transmits the first signal to a gate terminal of the first transistor in the gaze zone via the first conductive line when the gaze direction is toward the gaze zone.

13. The driver IC of claim 12, wherein the signal generating circuit is further arranged to generate a second signal toward a second conductive line of the display panel, and the selecting circuit is further arranged to transmit the second signal to a gate terminal of a second transistor in the pixel array via the second conductive, and the selecting circuit transmits the second signal to the gate terminal of the first transistor via the first conductive line when the gaze direction is toward a part of the display panel, and the part of the display panel excludes the gaze zone.

14. The driver IC of claim 12, further comprising:
a control circuit, arranged to generate a control signal according to the gaze direction;
wherein the selecting circuit includes a switch controlled by the control signal, and the selecting circuit transmits the first signal to the first transistor via the first conductive line when the control signal activates the switch.

15. A display system, comprising:
an image sensor, arranged to capture a gaze direction of an observer;
a display panel, including:
a plurality of pixels, arranged in a pixel array; and
a plurality of conductive lines, wherein a part of each conductive line straightly extends from one side of the pixel array to an opposite side of the pixel array and couples to each transistor located thereon; and
a driver integrated circuit (IC), including:
a signal generating circuit, arranged to generate a first signal and a second signal;
a selecting circuit, arranged to the first signal to a first conductive line, and further arranged to selectively transmit the second signal to a second conductive line according to the gaze direction, wherein the second conductive is adjacent to the first conductive line.

16. The display system of claim 15, the selecting circuit transmits the first signal to the first conductive line and the second conductive line when the gaze direction is toward a part of the display panel, and the part of the display panel excludes a zone of the display panel covering the first conductive line and the second conductive line.

17. The display system of claim 15, wherein the selecting circuit transmits the first signal to the first conductive line and the second signal to the second conductive line when the gaze direction is toward a zone of the display panel covering the first conductive line and the second conductive line.

18. A driving method of a display system, comprising:
arranging a plurality of pixels in a display panel of the display system in a pixel array, wherein the pixel array includes a first number of rows, and each row includes a conductive line;
coupling a second number of transfer lines to the conductive lines in the first number of rows, wherein the first number is greater than the second number; and
selectively transmitting signals carried on the second number of transfer lines to the transistors located in the first number of rows according to a gaze direction of an observer.

19. The method of claim 18, further comprising:
capturing the gaze direction of the observer by an image sensor;
generating a first signal and a second signal;
transmitting the first signal on a first transfer line to a first conductive line of the display system;
wherein selectively transmitting signals carried on the second number of transfer lines to the transistors located in the first number of rows according to the gaze direction of the observer includes:
transmitting the first signal on the first transfer line to the second conductive line when the gaze direction is toward a part of the display panel, wherein the part of the display panel excludes a zone of the display panel covering the first conductive line and the second conductive line.

20. The method of claim 19, wherein selectively transmitting signals carried on the second number of transfer lines to the transistors located in the first number of rows according to the gaze direction of the observer further includes:
transmitting the second signal on a second transfer line to the second conductive line when the gaze direction is toward the zone of the display panel covering the first conductive line and the second conductive line.
